(19) United States
(12) Patent Application Publication
(10) Pub. No.: US 2020/0124994 A1
(43) Pub. Date: Apr. 23, 2020

(54) MASK TREATING METHOD AND SYSTEM THEREOF

(71) Applicant: TAIWAN SEMICONDUCTOR MANUFACTURING COMPANY LTD., Hsinchu (TW)

(72) Inventors: WU-HUNG KO, TAINAN CITY (TW); CHUNG-HUNG LIN, TAINAN CITY (TW); CHIH-WEI WEN, TAINAN CITY (TW)

(21) Appl. No.: 16/168,114

(22) Filed: Oct. 23, 2018

(51) Int. Cl. G03F 7/20; G03F 1/72; G03F 1/82

(52) U.S. Cl. CPC G03F 7/70925; G03F 1/82; G03F 1/72

(57) ABSTRACT

The present disclosure provides a method of treating a mask for photolithography. The method includes disposing the mask on a stage in a tool. The mask includes a pellicle and a substrate. The method further includes providing oxygen gas in a space between the pellicle and the substrate, and splitting the oxygen gas in the space to form an oxygen atom or an ozone molecule. The method further includes exposing surfaces of the pellicle and the substrate to the oxygen atom or the ozone molecule for a predetermined duration. A mask treating system is also provided.

### BACKGROUND

In the semiconductor manufacture, cleaning is one of the most important aspects of photomask (hereinafter referred to as “mask”) manufacturing and maintenance because even the smallest contaminating particles may transfer defects on wafers in a patterning operation, and such particles can destroy integrated circuit. To make sure the mask meets the manufacture requirement, the mask is scheduledly sent from a photolithographic patterning apparatus to a mask cleaning apparatus.

The current mask cleaning requires the mask to be de-pellicle and wet cleaned, which may cause mask scraps and decay. Site transportation, de-pellicle, wet cleaning, and other operations, such as critical dimension measurement, phase measurement, pellicle mounting, and inspection, are time-consuming. Besides, many qualification factors need to be followed in those operations. It is within this context the following disclosure arises.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic functional block diagram of a mask treating system with an in-situ cleaning tool, in accordance with some embodiments of the present disclosure.

FIG. 2 is a flow chart of a method of treating a mask for photolithography in accordance with some embodiments of the present disclosure.

FIG. 3 is a flow chart of a method of treating a mask for photolithography in accordance with some embodiments of the present disclosure.

FIGS. 4 and 5 illustrate a mechanism of a cleaning operation, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

To make sure the mask for photolithography meets the manufacture requirement, the mask is scheduledly cleaned. However, the current mask cleaning operation may inevitably destroy the mask, and is complex and time-consuming. Therefore, the present disclosure provides a method of treating a mask for photolithography. The method includes disposing the mask on a stage in a tool. The mask includes a pellicle and a substrate. The method further includes providing oxygen gas in a space between the pellicle and the substrate, and splitting the oxygen gas in the space to form an oxygen atom or an ozone molecule. The method further includes exposing surfaces of the pellicle and the substrate to the oxygen atom or the ozone molecule for a predetermined duration. The method of the present disclosure can clean the mask for photolithography in a way which has lower risk of contamination and is more convenient and efficient.

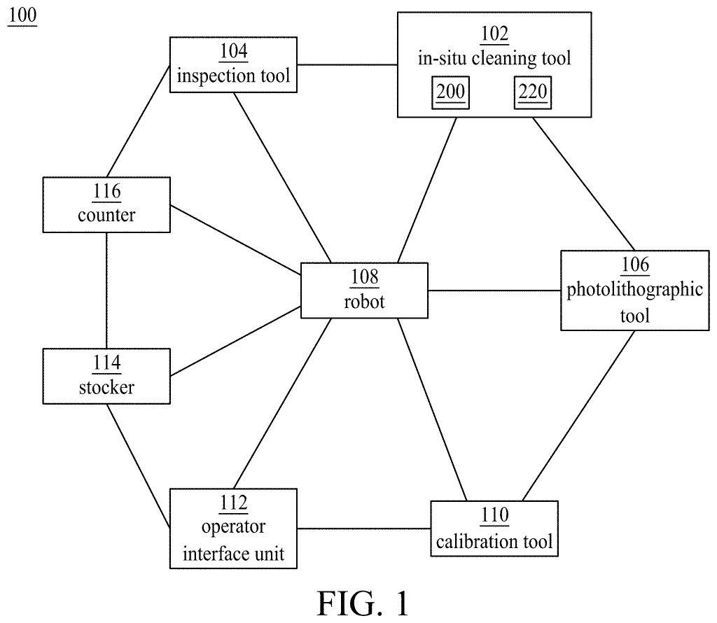

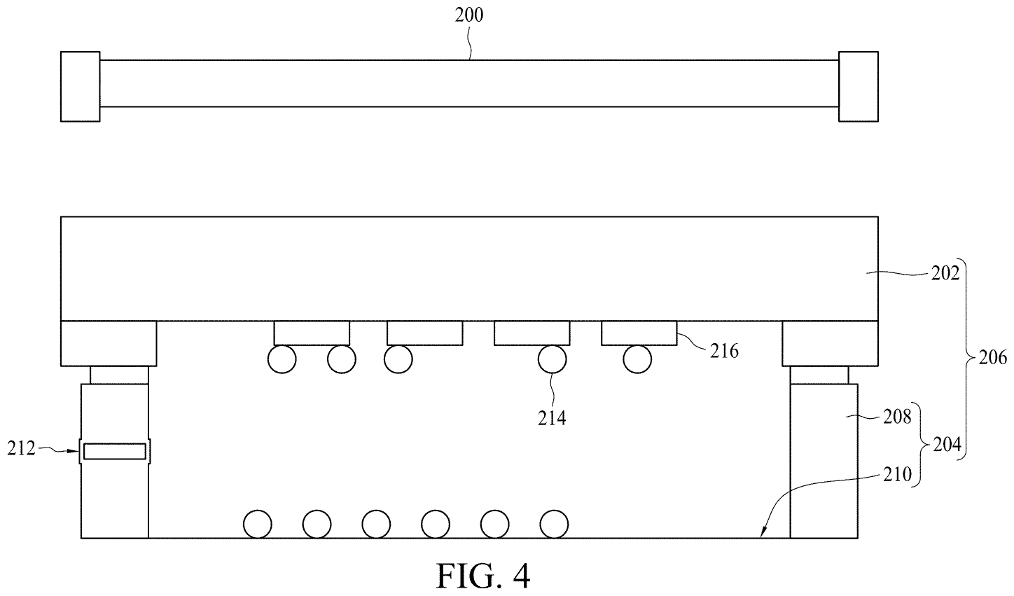

Referring to FIG. 1, FIG. 1 is a schematic functional block diagram of a mask treating system 100 with an in-situ cleaning tool 102, in accordance with some embodiments of the present disclosure. The mask (such as the mask 206 in FIG. 4) may be utilized in a photolithography operation of a semiconductor wafer.

In some embodiments, the mask treating system 100 includes an inspection tool 104 for inspecting the mask and/or performing other quality-checking operations before and/or after the mask is applied in a photolithographic operation. In some embodiments, the in-situ cleaning tool 102 is integrated with and coupled with the inspection tool 104. In such a way, a cleaning operation can be performed in the inspection tool 104.

In some embodiments, the mask treating system 100 is for photolithography process. In such embodiments, the mask treating system 100 may include a photolithographic tool 106 configured to perform a photolithographic operation. Alternatively, the inspection tool 104 of the mask treating system 100 may be coupled with a photolithographic tool or is part of a photolithographic system. In some embodiments, the in-situ cleaning tool 102 is integrated with and coupled with the photolithographic tool 106. In such a way, a cleaning operation can be performed in the photolithographic tool 106.

In some embodiments, the wafer to be patterned may be positioned on the substrate stage (not shown) under the mask. The wafer is positioned to receive the radiation transmitted through or reflected off the mask. The image on the wafer corresponds to the pattern on the mask. The image is utilized on the wafer to pattern a radiation light sensitive coating layer. The radiation light sensitive coating layer can be utilized to define doping regions, deposition regions, etching regions, or other structures associated with an integrated circuit (IC). In some embodiments, the radiation light sensitive coating layer may include a positive tone resist or a negative tone resist.

The terms “radiation” and “light” used herein encompass all types of electromagnetic radiation, including ultraviolet (UV) radiation, deep UV (DUV) radiation, and extreme UV (EUV) radiation, as well as particle beams, such as ion beams or electron beams. In some embodiments, the radiation source used to pattern the wafer may be a mercury lamp having a wavelength of 436 nm (G-line) or 365 nm (I-line); a Krypton Fluoride (KrF) excimer laser with wavelength of 248 nm; an Argon Fluoride (ArF) excimer laser with a wavelength of 193 nm; a Fluoride (F₂) excimer laser with a wavelength of 157 nm; EUV radiation source with a wavelength of 13.5 nm; or other light sources having a desired wavelength. In some embodiments, the radiation source used to pattern the wafer may also be used to clean the mask in the in-situ cleaning tool 102. In some embodiments, the in-situ cleaning tool 102 has its own radiation source, such as a radiation source 200.

In some embodiments, the mask treating system 100 may also include a robot 108 for transporting the mask, and a calibration tool 110 for position the mask. In some embodiments, the mask treating system 100 may also include an operator interface unit 112, a stocker 114 and a counter 116. In some embodiments, the in-situ cleaning tool 102 includes the radiation source 200. In some embodiments, the in-situ cleaning tool 102 includes a stage 220.

In some embodiments, the units or operation stations in the mask treating system 100 may be configured to stand alone or integrated with and coupled with each other.

Although specific units for achieving particular functions are described herein, the present disclosure is not limited thereto. Other configurations and inclusion or omission of the mask treating system 100 may be possible and within the scope of the present disclosure. For examples, the mask treating system 100 may further include a track system using wafer handling equipment, which is able to transport the wafers between the various photolithography operation stations.

In some embodiments, the inspection tool 104 is configured to inspect defect on the mask received in the mask treating system 100. In order to ensure that the wafer can be exposed correctly and consistently, it is desirable to check quality of the mask scheduledly, so as to ensure that the mask applied in every photolithographic operations meets requirements. In such a situation, the mask is scheduledly or periodically transported to the inspection tool 104 for quality checking before and/or after the mask is applied in a photolithographic operation. In some embodiments, the mask is checked at regular time intervals. In some embodiments, the mask is checked after a predetermined operation times. In some embodiments, the mask may be sent from the photolithographic tool 106, sent from the stocker 114, or sent from photolithographic tool apart from the mask treating system 100.

After the mask is inspected and checked by the inspection tool 104, a cleaning operation may proceed through the in-situ cleaning tool 102 if it is necessary. For examples, the mask is deemed un-qualified when the defects on the mask is too much or exceeds a predetermined baseline, and a cleaning operation may be performed.

In some embodiments, as mentioned above, the in-situ cleaning tool 102 may be integrated with and coupled with the inspection tool 104. In some embodiments, the in-situ cleaning tool 102 and the inspection tool 104 may be integrated in a same chamber of the mask treating system 100. In some embodiments, the in-situ cleaning tool 102 shares the same chamber with the inspection tool 104 and the inspection and cleaning operation are performed in the same chamber.

In some embodiments, the cleaning operation can be done soon and fast enough that another wafer of the same batch is still waiting to be processed in the photolithographic tool 106. In some embodiments, the cleaning operation can be performed simultaneously while the mask is used in a photolithographic operation. In some embodiments, the cleaning operation can be performed in an interval between two photolithographic operations. In some embodiments, after the inspection operation and/or the cleaning operation, the mask may be sent to the stocker 114 by the robot 108 for storage. In some embodiments, after the inspection operation and/or the cleaning operation, the mask may be sent to the photolithographic tool 106 by the robot 108 for another photolithographic operation.

In some embodiments, the quality check operation includes inspecting patterns on the mask. In some embodiments, the quality check operation may be practiced through photolithography simulation and measurement of critical dimensions. For example, the quality check operation includes converting the predetermined layout pattern into a rendered mask pattern through an inverse image rendering process. Then, a photolithography operation may be simulated using the rendered mask pattern to create a virtual wafer pattern. Finally, based on the virtual wafer pattern, defects on the mask can be determined.

In some embodiments, the robot 108 is configured to transfer the mask between different positions and tools in the mask treating system 100. In some embodiments, the robot 108 may be also used to transport the mask in/out with respect to the mask treating system 100.

The robot 108 may be a track system using handling equipment, which transfers the mask between the various operation stations in the mask treating system 100. In some embodiments, the robot 108 may be an automated track system enables various processing operations to be carried out simultaneously. For examples, a mask is cleaned and sent back to the stock 114, while another mask is moved forward to the inspection tool 104 after finishing an exposuring operation in the photolithographic tool 106.

In some embodiments, the calibration tool 110 is configured to perform an alignment calibration operation before and/or after the mask is transferred. There are various techniques for making calibration in photolithographic processes, including the use of scanning electron microscopes or other measurement tools coupled with the other tools, such as the robot 108 and the stages. The calibration tool 110 may be configured to a stand-alone unit outside the mask treating system 100, or may be configured to a module integrated in the mask treating system 100.

In some embodiments, the operator interface unit 112 is capable of controlling the operations performed in the mask treating system 100. In some embodiments, the operator interface unit 112 is also capable of controlling the environments under which the mask and, if any, the wafer, are processed. In some embodiments, the operator interface unit 112 includes a calculator, a central processing unit (CPU), a computer, or other capable unit known in the arts. In some embodiments, the operator interface unit 112 includes a display screen. In some embodiments, the operator interface unit 112 also includes mouses, trackballs, trackmarbles or other pointing devices. In some embodiments, the operator interface unit 112 also includes key boards, acoustic input devices, touch sensors, or other input devices. In some embodiments, the operator interface unit 112 is distributed in an intranet or a portion of the Internet coupled with a semiconductor manufacturer.

In some embodiments, the stocker 114 is for the storage of the mask. In some embodiments, the stocker 114 includes a chamber suitable for maintaining the mask during a stocker idle time.

In some embodiments, the counter 116 counts a wafer exposuring operation count. In some embodiments, the wafer exposuring operation count is defined as the exposuring times of a same mask. For examples, pattern a wafer by a mask is considered as an exposuring operation No. 1. Then the subsequent patterning by the same mask is considered as an exposuring operation No. 2, regardless of whether the wafer is the same, and also regardless of whether the mask is transferred to another station for performing other operation. In other words, the wafer exposuring operation count is the number of times that the mask is being used. In some embodiments, the counter 116 is programmed and set up with a particular condition and count number for a mask, and then track the mask for obtaining the exposuring operation count.

In some embodiments, the counter 116 counts the stocker idle time of the mask. In some embodiments, the stocker idle time is defined as the duration of a mask placed in the stocker 114. In some embodiments, the wafer exposuring operation count may be a variation or a range as a reference of whether a cleaning operation is needed. Also, in some embodiments, the stocker idle time may be a variation or a range as a reference whether a cleaning operation is needed. In some embodiments, the cleaning operation is also related to the life time, the transporting tracks, and other factors.

In some embodiments, the photolithographic tool 106 is configured to expose a pattern of the mask to the wafer received in. In some embodiments, the photolithographic tool 106 includes various processing tools and metrology tools coupled together and configured to perform various processes such as coating, alignment, exposure, developing, and/or other processes. In some embodiments, the photolithographic tool 106 may encompass various types of optical components, including refractive, reflective, and catadioptric optical components for directing, shaping, or controlling the beam of radiation.

In some embodiments, the in-situ cleaning tool 102 may be integrated with and coupled with the photolithographic tool 106. In some embodiments, the in-situ cleaning tool 102 may couple with the photolithographic tool 106 through the inspection tool 104. In some embodiments, the in-situ cleaning tool 102 and the photolithographic tool 106 may be integrated in a same chamber of the mask treating system 100. In some embodiments, the in-situ cleaning tool 102 shares the same chamber with the photolithographic tool 106, and the photolithographic operation and the cleaning operation are performed in the same chamber.

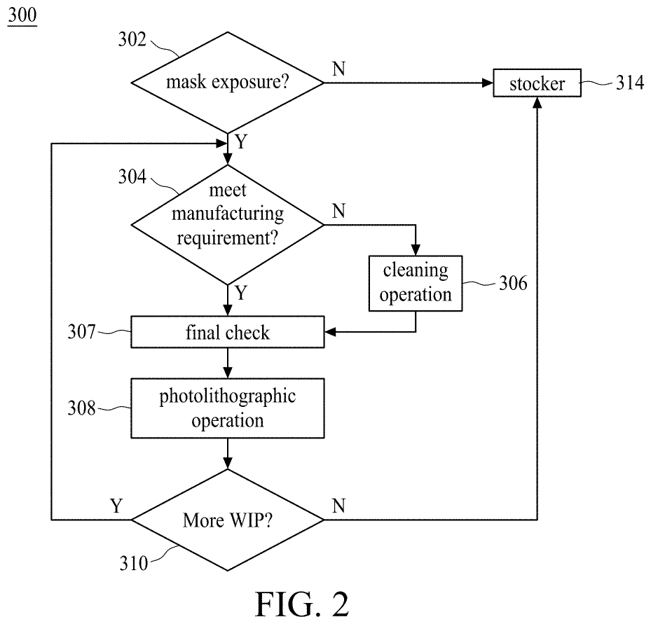

Referring to FIG. 2, FIG. 2 is a flow chart of a method 300 of treating a mask for photolithography in accordance with some embodiments of the present disclosure. The method 300 is described with reference to FIG. 1 hereafter.

The method 300 begins at block 302, determining whether the mask is going to be applied in a production environment, such as being applied in a photolithographic operation. The mask may be placed in the stocker 114, just finished another photolithographic operation in the photolithographic tool 106, or just undergone an inspection operation in the inspection tool 104.

If the mask is going to be applied in a production environment, then the method 300 proceeds to block 304, to check if the mask meets the manufacturing requirements, and therefore, to decide if a cleaning operation is needed before applying the mask. On the other hand, if the mask is not going to be applied, the mask may be sent back to the stocker 114. In some embodiments, the mask may also undergo a cleaning operation before sent back to the stocker 114.

In block 304, the mask is checked by various criteria, for examples, the information about the defects, the wafer exposuring operation count, and the stocker idle time obtained through the counter 116. In some embodiments, the quality check operation through the inspection tool 104 takes other factors into consideration for determining if a cleaning operation is needed.

In some embodiments, the method 300 further includes counting a wafer exposuring operation count. In some embodiments, the method 300 further includes counting a stocker idle time of the mask. In some embodiments, the counting operation is performed by the counter 116. In some embodiments, the counting operation may be performed throughout the method 300. In some embodiments, the counting results may be obtained by the counter 116, and accessed by the operator interface unit 112.

If a cleaning operation is needed, the method 300 proceeds to block 306, to clean the mask through the in-situ cleaning tool 102. In some embodiments, the in-situ cleaning tool 102 shares the same chamber with the inspection tool 104, and the inspection operation and cleaning operation are performed in the same chamber. After the cleaning operation, the method 300 proceeds to block 307, to perform a final check. The operations of checking and cleaning in blocks 304, 306, and 307 can be repeated until the mask meets the requirements. The detail descriptions of the final check can refer to the block 304 described above.

If a cleaning operation is not needed, the method 300 proceeds to block 307. After the final check, the mask is sent to the production environment in block 308, such as the photolithographic tool 106. In some embodiments, the in-situ cleaning tool 102 shares the same chamber with the photolithographic tool 106, and the photolithographic operation and the cleaning operation are performed in the same chamber. In some embodiments, a pattern on the mask is exposed to a wafer in block 308.

After the mask is applied in a photolithographic operation for a predetermined duration, for number of times, or for a predetermined amount of wafers, the method 300 proceeds to block 310, determining if there are more wafers in process (WIP), and if more operations are needed. The mask may be sent back to the stocker 114. Alternately, the mask may go through another step in the method 300.

It is should be noticed that, in addition to be applied in a production environment of the wafer, the cleaning operation provided in the present disclosure can also be used to clean a mask after it has been manufactured.

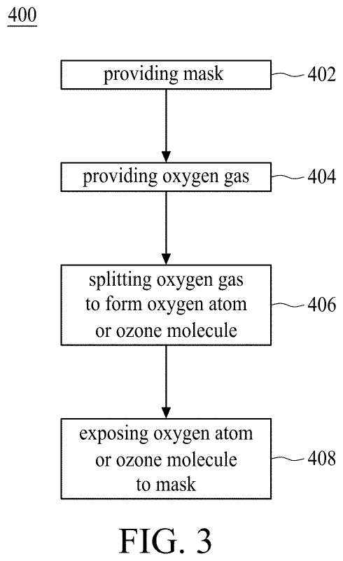

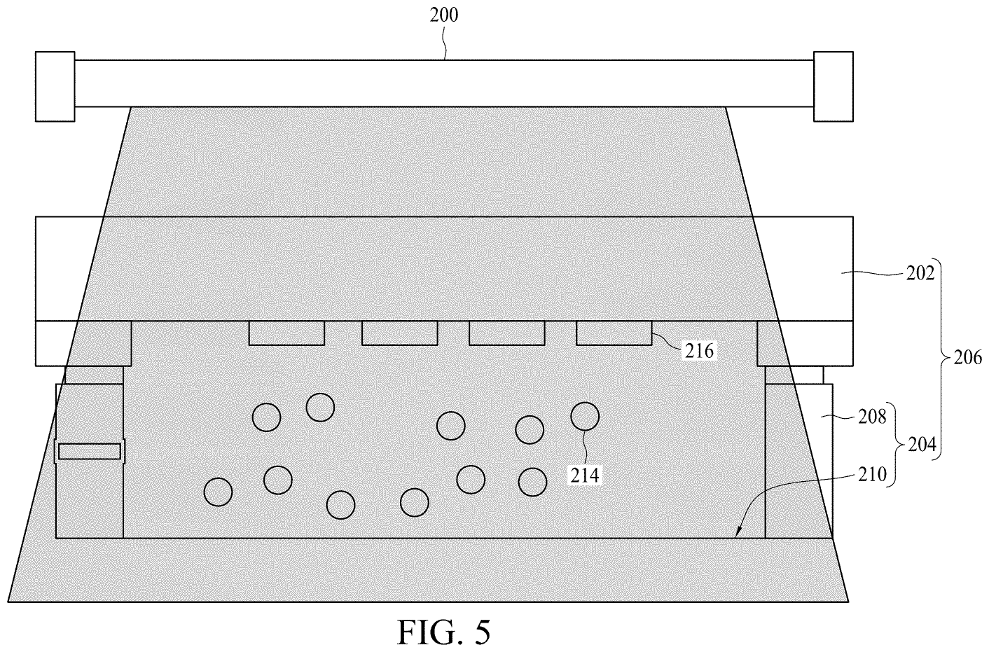

Referring to FIG. 3, FIG. 3 is a flow chart of a method 400 of treating a mask for photolithography in accordance with some embodiments of the present disclosure. In some embodiments, the method 400 can be parts of the method 300. The method 400 is described with reference to FIGS. 4 and 5. FIGS. 4 and 5 illustrate a mechanism of a cleaning operation, in accordance with some embodiments of the present disclosure.

The method 400 begins at block 402, providing the mask 206. In some embodiments, the mask 206 is provided on the stage 220 (not shown in FIGS. 4 and 5), which is configured to support the mask 206. In some embodiments, the stage is also configured to position the mask 206 with respect to the radiation source 200.

In some embodiments, the mask 206 includes a substrate 202 and a pellicle 204 attached to the substrate 202. The pellicle 204 includes a membrane 210 and a frame 208, collectively referred as the pellicle 204. The frame 208 secures the membrane 210 on the substrate 202. The membrane 210 is a thin film that is mounted over the frame 208. The pellicle 204 of the mask 206 protects the mask 206 from fallen particles and keeps the particles out of focus so that they do not produce an image, which may cause defects when the mask 206 is being used.

In some embodiments, the mask 206 further includes a pattern layer 216 on a surface of the substrate 202. The membrane 210 is between the pattern layer 216 and ambient. The membrane 210 isolates the pattern layer 216 from ambient. In some embodiments, the pattern layer 216 includes metal silicide (such as MoSi or TaSi₂), metal nitride (such as TiN, ZrN, NbN, MoN, CrN, or TaN), metal oxide (such as MoO₃, Cr₂O₃, TiO₂, Nb₂O₅, or Ta₂O₅), other materials such as Cr, Mo, Ti, Ta, SiO₂, Si₃N₄, Al₂O₃N, Al₂O₃R, or combinations thereof. In some embodiments, there are multiple layers on the substrate 202, which are collectively referred as the pattern layer 216 in the present application. For example, the multiple layers include a reflective multilayer, a capping layer, an absorption layer, an antireflection (ARC) layer, and/or a buffer layer.

Any use of the term “mask” herein may be considered synonymous with the more general term “patterning device.” The term “patterning device” used herein should be broadly interpreted as referring to any device that can be used to impart a radiation beam with a pattern in its cross-section such as to create a pattern in a target portion of the wafer. The patterning device may be transmissive or reflective. The type of the mask is associated with the type of the photolithographic tool 106 where the mask is applied. Examples of patterning devices include masks, programmable mirror arrays, and programmable LCD panels. Masks are well known in lithography, and include mask types such as binary, alternating phase-shift, and attenuated phase-shift, as well as various hybrid mask types.

In some embodiments, the stage may use mechanical, vacuum, electrostatic or other clamping techniques to hold the mask. In some embodiments, the stage may be fixed or movable as required. For examples, the stage can move between the operations stations in the mask treating system 100 with the mask secured on it. Alternatively, the mask may be transferred without moving the stages, and the stages are fixed in the respective operation stations.

In some embodiments, the stage may be in a chamber (not shown in the figures) of the mask treating system 100. In some embodiments, the chamber is for providing a low pressure environment. In some embodiments, the chamber is for providing a pressure below about 1 atmosphere during the exposing operation, in which the mask is exposed to the radiation source 200. As mentioned above, the chamber may be shared between the operations stations in the mask treating system 100, such as shared between the in-situ cleaning tool 102 and the photolithographic tool 106, and/or shared between the in-situ cleaning tool 102 and the inspection tool 104.

As shown in FIG. 4, there may be some contaminants, such as organic residues 214 on surfaces of the substrate 202 and the pellicle 204. In some embodiments, the organic residues 214 include halo, haze, or other residues which are composed of carbon, hydrogen, and oxygen.

The method 400 proceeds to block 404, providing oxygen gas. In some embodiments, the oxygen gas is provided through a vent hole 212 on the frame 208. In some embodiments, the oxygen gas is maintained in the chamber containing the mask 206. In some embodiments, the oxygen gas already exists in the chamber.

In some embodiments, the oxygen gas fills space between the substrate 202 and the pellicle 204 while the pellicle 204 is disposed on the substrate 202. In some embodiments, the oxygen gas in the space between the substrate 202 and the pellicle 204 reaches a predetermined concentration.

The method 400 proceeds to block 406, splitting the oxygen gas to form oxygen atom or ozone molecule. In some embodiments, splitting the oxygen gas includes introducing a light into the space. In some embodiments, the oxygen gas may be split to from oxygen atom or ozone molecule by other mechanisms.

In some embodiments, the in-situ cleaning tool 102 includes the radiation source 200. In some embodiments, the radiation source 200 provides radiation energy. In some embodiments, the radiation source 200 provides a vacuum UV (VUV) radiation. In some embodiments, the VUV radiation includes a wavelength in the range of about 10 nm to about 180 nm. In some embodiments, the VUV radiation includes a wavelength of 172 nm. In some embodiments, the radiation source 200 exposes a VUV radiation on the surfaces of the substrate 202 and the pellicle 204 simultaneously. In some embodiments, the mask 206 may be exposed by the VUV radiation without removing the pellicle 204 from the substrate 202.

The method 400 proceeds to block 408, exposing oxygen atom or ozone molecule to the mask. In some embodiments, the exposing operation lasts for a predetermined duration.

In some embodiments, method 400 further includes reacting the organic residues on the exposed surfaces with the oxygen atom or the ozone molecule. In some embodiments, the pellicle 204 is disposed on the substrate 202 throughout the flow process of method 400. As shown in FIG. 5, the bonds of the organic residues 214 are break, and the organic residues 214 are no longer stick to the exposed surfaces.

In some embodiments, the ozone molecule oxidizes the elements in the organic residues to their respective oxides. In some embodiments, the oxygen atom reacts with the organic residues and produces CO₂, and/or H₂O. In some embodiments, the reaction products may be exhausted through the vent hole 212. In some embodiments, hot or gas may be utilized to help removing the reaction products.

Some embodiments of the present disclosure provide a method of treating a mask for photolithography. The method includes disposing the mask on a stage in a tool. The mask includes a pellicle and a substrate. The method further includes providing oxygen gas in a space between the pellicle and the substrate, and splitting the oxygen gas in the space to form an oxygen atom or an ozone molecule. The method further includes exposing surfaces of the pellicle and the substrate to the oxygen atom or the ozone molecule for a predetermined duration.

Some embodiments of the present disclosure provide a method of treating a mask for photolithography. The method includes receiving a mask in a tool. The mask includes a pellicle and a substrate. The method further includes cleaning the mask by reacting contaminants on the mask with an oxygen atom or an ozone molecule while the pellicle is disposed on the substrate.

Some embodiments of the present disclosure provide a mask treating system. The system includes a VUV radiation source and a mask stage for supporting a mask. The mask includes a substrate and a pellicle disposed on the substrate. The VUV radiation source is configured to expose a VUV radiation on surfaces of the pellicle and the substrate simultaneously.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of treating a mask for photolithography, comprising:
disposing the mask on a stage in a tool, wherein the mask includes a pellicle and a substrate;
providing oxygen gas in a space between the pellicle and the substrate;
splitting the oxygen gas in the space to form an oxygen atom or an ozone molecule; and
exposing surfaces of the pellicle and the substrate to the oxygen atom or the ozone molecule for a predetermined duration.

2. The method of claim 1, wherein exposing surfaces of the pellicle and the substrate to the oxygen atom or the ozone molecule for a predetermined duration includes reacting an organic residue on the exposed surfaces with the oxygen atom or the ozone molecule.

3. The method of claim 1, wherein splitting the oxygen gas in the space to form an oxygen atom or an ozone molecule includes introducing a light into the space.

4. The method of claim 3, wherein the light is a vacuum ultraviolet (VUV) radiation.

5. The method of claim 1, wherein the stage is in a chamber of the tool.

6. The method of claim 1, wherein the tool is an inspection tool for detecting defect on the mask.

7. The method of claim 1, further comprising inspecting defect on the mask in the tool.

8. The method of claim 1, wherein the tool is for photolithography process.

9. The method of claim 1, further comprising exposuring a pattern on the substrate to a semiconductive wafer in the tool.

10. The method of claim 1, further comprising counting a wafer exposuring operation count.

11. The method of claim 1, further comprising counting a stocker idle time of the mask.

12. A method of treating a mask for photolithography, comprising:
receiving a mask in a tool, wherein the mask includes a pellicle and a substrate;
cleaning the mask by reacting contaminants on the mask with an oxygen atom or an ozone molecule while the pellicle is disposed on the substrate.

13. The method of claim 12, further comprising using the mask in a lithographic operation before the cleaning operation, and re-using the mask in another lithographic operation, wherein the lithographic operation and the cleaning operation are performed in the same tool.

14. The method of claim 13, further comprising inspecting defect on the mask in the same tool.

15. The method of claim 12, further comprising exposing surfaces of the pellicle and the substrate to a VUV radiation including a wavelength in the range of about 10 nm to about 180 nm.

16. The method of claim 12, further comprising providing oxygen gas in a space between the pellicle and the substrate.

17. A mask treating system, comprising:
a VUV radiation source; and
a mask stage for supporting a mask comprising a substrate and a pellicle disposed on the substrate;
wherein the VUV radiation source is configured to expose a VUV radiation on surfaces of the pellicle and the substrate simultaneously.

18. The mask treating system of claim 17, further comprising a chamber for providing a pressure below about 1 atmosphere during the exposing operation.

19. The mask treating system of claim 17, further comprising a photolithographic tool configured to perform a lithographic operation.

20. The mask treating system of claim 17, further comprising an inspection tool configured to perform an inspection operation.
